(19) United States
(12) Patent Application Publication
(10) Pub. No.: US 2025/0318437 A1
(43) Pub. Date: Oct. 9, 2025

(54) MAGNETORESISTIVE DEVICE

(71) Applicant: Infineon Technologies AG, Neubiberg (DE)

(72) Inventors: Dieter SUESS, Herzogenburg (AT); Claas ABERT, Herzogenburg (AT); Armin SATZ, Villach (AT); Johannes GÜTTINGER, Lind ob Velden (AT); Klemens PRÜGL, Regensburg (DE)

(21) Appl. No.: 19/065,692

(22) Filed: Feb. 27, 2025

(30) Foreign Application Priority Data
Mar. 14, 2024 (DE) 102024107234.2

(51) Int. Cl. H10N 50/10; G01R 33/09; G11C 11/16; H01F 10/32; H10N 50/85

(52) U.S. Cl. CPC H10N 50/10; G01R 33/093; G01R 33/098; G11C 11/161; G11C 11/1675; H01F 10/3272; H01F 10/3286; H10N 50/85

(57) ABSTRACT

Provided is a magnetoresistive device including at least one magnetoresistive element including a layer stack of ferromagnetic layers and non-magnetic layers stacked in a first direction. The layer stack includes a ferromagnetic layer having a magnetic orientation to be switched. Adjacent to the ferromagnetic layer, a first conductor extends in a second direction and a second conductor extends in a third direction. The first and second conductors are configured to induce spin-orbit torque, SOT, in the ferromagnetic layer. A control circuit is configured to apply a first current pulse to the first conductor and a second current pulse to the second conductor in a temporally overlapping manner and with different time characteristics. For example, the control circuit may be configured to turn off the second current pulse before turning off the first current pulse to switch the magnetic orientation of the ferromagnetic layer.

### CROSS-REFERENCE TO RELATED APPLICATION

This application claims priority to Germany Patent Application No. 102024107234.2 filed on Mar. 14, 2024, the content of which is incorporated by reference herein in its entirety.

### FIELD

The present disclosure generally relates to magnetoresistive (MR) devices and, more particularly to switching magnetizations in MR devices using the spin-orbit torque (SOT) effect.

### BACKGROUND

Conventional magnetic sensing devices which are based on materials showing a magnetoresistance effect (e.g., AMR, GMR, TMR) may be limited regarding their ability to measure static magnetic field components in a very accurate way. An offset error in this kind of devices depends on device-to-device matching which may be dominated by manufacturing limits. The same argumentation is also true for Hall effect devices, but an advantage of a Hall device is the possibility to cancel out first order mismatches by applying a so-called spinning current technique. In order to implement offset-reducing signal conditioning methods for magnetoresistive devices, magnetization directions in defined magnetic layers have to be changed or controlled by electrical signals (e.g., currents).

Offset reducing signal conditioning methods for magnetoresistive devices are known for AMR sensing devices, for example. With chip-external or-internal coils, an AMR transfer curve can be inverted by changing magnetization direction, so-called flipping AMR principle. A drawback of this principle is the current consumption needed for reaching AMR flipping fields.

Recently, the use of the spin-orbit torque (SOT) effect has been proposed in order to switch the magnetic layer of the reference system (Luo, K., Guo, Y., Li, W., Zhang, B., Wang, B., and Cao, J.: “Implementation of a full Wheatstone-bridge GMR sensor by utilizing spin-orbit torque induced magnetization switching in synthetic antiferromagnetic layer”, Journal of Applied Physics). With this technique, larger signal ranges with lower current consumption may be realized compared to flipping AMR. In commonly used SOT switching schemes a bias field is required to allow deterministic switching. Methods to reduce the bias field are summarized in Krizakova, V., Perumkunnil, M., Couet, S., Gambardella, P., and Garello, K.: “Spin-orbit torque switching of magnetic tunnel junctions for memory applications”, Journal of Magnetism and Magnetic Materials.

Thus, there is a demand for switching the magnetic layer of the reference system without required bias fields.

### SUMMARY

This demand is addressed by magnetoresistive devices and methods in accordance with the appended claims.

According to a first aspect, the present disclosure provides a magnetoresistive (MR) device. The MR device includes at least one MR element. The MR element may be a MR sensing element or a MR memory element. The MR element may have a spin-valve structure. The MR element includes a layer stack with ferromagnetic and non-magnetic layers stacked in a first direction. For example, the first direction may be a vertical direction (e.g., z-direction). The layer stack of the MR element includes a ferromagnetic layer whose magnetic orientation is to be switched. The ferromagnetic layer may be a reference layer/system or a magnetic free layer of the MR element. The MR device further includes, adjacent to the ferromagnetic layer, a first conductor extending in a second direction (e.g., x-direction) and a second conductor extending in a third direction (e.g., y-direction). The second and third directions may span a plane to which the first direction is perpendicular. For example, the second direction (e.g., x-direction) may be perpendicular to the first direction (e.g., z-direction). The third direction (e.g., y-direction) may be perpendicular to the first direction (e.g., z-direction) and/or second direction (e.g., x-direction). The first and second conductors are configured to induce spin-orbit torque (SOT) in the ferromagnetic layer adjacent to the first and second conductors. The MR device further includes a control circuit configured to apply a first current pulse to the first conductor and a second current pulse to the second conductor in a temporally overlapping manner. That is, the first current pulse and the second current pulse overlap in time. The control circuit is further configured to apply the first and the second current pulse with different respective time characteristics. This means that the first and the second current pulse may vary in one or more aspects related to their temporal properties. These differences may include variations in duration or amplitude variations, for example. The current pulses may take any functional form.

For example, the control circuit may be configured to vary a relative strength of the first current pulse and the second current pulse during the application of the first current pulse and/or the second current pulse.

In some implementations, the control circuit may be configured to turn off the second current pulse (e.g., turn current strength of the second current pulse to zero or close to zero) before turning off the first current pulse.

In this way, a magnetization of the ferromagnetic layer may be switched without a magnetic bias field.

In some implementations, the ferromagnetic layer whose magnetic orientation is to be switched is a magnetic reference layer. More particularly, the ferromagnetic layer may be part of a synthetic antiferromagnet (SAF) including a first and a second ferromagnetic layer separated by a non-magnetic layer. The SAF may be used as a magnetic reference layer of the MR sensing element. A SAF in the context of MR devices is a structure configured to mimic the behavior of antiferromagnetic materials through a synthetic stack of ferromagnetic layers separated by a non-magnetic conducting or insulating spacer layer. A characteristic of a SAF is the antiparallel alignment of the magnetic moments in the ferromagnetic layers, which is achieved through indirect magnetic coupling mediated by the spacer layer. A typical SAF structure includes two (or more) thin ferromagnetic layers (such as CoFe or NiFe) separated by a very thin non-magnetic layer (commonly Ruthenium, Ru, for its unique ability to induce antiferromagnetic coupling at certain thicknesses). The thickness of the Ru layer may be controlled to a few atomic layers to ensure that the RKKY (Ruderman-Kittel-Kasuya-Yosida) interaction or other exchange coupling mechanisms can induce a strong antiparallel alignment between the magnetic moments of the adjacent ferromagnetic layers.

In some implementations, the ferromagnetic layer whose magnetic orientation is to be switched is a magnetic free layer. The magnetic free layer may be separated from the magnetic reference layer (e.g., SAF) by a non-magnetic layer. In some implementations, the non-magnetic layer between the free layer and the magnetic reference layer (e.g., SAF) is a tunnel barrier. A tunnel barrier is a key component in certain types of magnetoresistive devices, such as Tunnel Magnetoresistance (TMR) sensors and Magnetic Random Access Memory (MRAM) cells. It includes a thin, non-conductive or insulating layer that separates two ferromagnetic layers (e.g., free layer and reference layer). Despite being an insulator, the tunnel barrier is thin enough (typically a few nanometers) to allow for quantum tunneling of electrons between the two ferromagnetic layers. This phenomenon is the basis for the tunneling effect observed in these devices. The ability of electrons to tunnel through the barrier depends on the relative orientation of the magnetic moments in the ferromagnetic layers on either side of the barrier. When the magnetic moments are parallel to each other, the resistance to electron tunneling is lower, and when the moments are antiparallel, the resistance is higher. This change in resistance as a function of the magnetic orientation is called Tunnel Magnetoresistance (TMR). The tunnel barrier may be made from materials such as aluminum oxide (Al₂O₃) or magnesium oxide (MgO), which are insulators that can be made into very thin layers while maintaining their insulating properties.

In some implementations, the non-magnetic layer between the free layer and the magnetic reference layer (e.g., SAF) is a conducting spacer layer. In the context of MR devices, particularly those based on Giant Magnetoresistance (GMR) or Spin-Valve structures, a conducting spacer layer is a component that separates two ferromagnetic layers. Unlike the insulating tunnel barrier used in TMR devices, the conducting spacer layer is made of a non-magnetic metal and allows for the conduction of electrons between the ferromagnetic layers.

A primary role of the conducting spacer layer is to facilitate the transmission of electrons while preserving their spin orientation, which is essential for the GMR effect to occur. The GMR effect relies on the difference in electrical resistance encountered by electrons with spins aligned parallel or antiparallel to the magnetization of the ferromagnetic layers. When the magnetizations of the ferromagnetic layers are parallel, electrons with matching spin orientation can pass through the structure more easily, resulting in lower electrical resistance. Conversely, when the magnetizations are antiparallel, the resistance increases because electrons with certain spin orientations are scattered more. A material chosen for the conducting spacer layer may influence the overall performance of the MR device. Common materials for the spacer include copper (Cu), silver (Ag), or gold (Au), known for their good electrical conductivity and minimal interaction with the spin of the electrons.

In some implementations, the ferromagnetic layer whose magnetic orientation is to be switched is a ferromagnet with perpendicular anisotropy. A ferromagnet with perpendicular anisotropy (also known as perpendicular magnetic anisotropy, PMA) is a type of ferromagnetic material in which the easy axis of the magnetization is oriented perpendicular to the plane (out-of-plane) of the material, rather than lying in the plane (in-plane). This means that the magnetic moments of the atoms in the material prefer to align themselves perpendicular to the surface of the material, creating a magnetic field that points either up or down relative to the surface.

In some implementations, another ferromagnetic layer (e.g., free layer) of the layer stack and non-adjacent to the first/second conductor is a ferromagnet with perpendicular crystalline anisotropy. A ferromagnet with perpendicular crystalline anisotropy refers to a type of ferromagnetic material in which the crystalline structure inherently favors magnetic moments aligning perpendicular to the plane of the material. This property is known as perpendicular magnetic anisotropy (PMA) at the crystalline level and is determined by the material's crystal lattice structure. The anisotropy is a result of the directional dependence of the magnetic energy within the crystal, which makes it energetically more favorable for the spins in the material to orient themselves in a direction perpendicular to the surface.

In some implementations, another ferromagnetic layer (e.g., free layer) of the layer stack and non-adjacent to the first/second conductor is a ferromagnet including a predominant in-plane magnetization in absence of an external magnetic field, such as, e.g., a flux-closure state at zero external magnetic field. A ferromagnet forming a flux-closure state at zero external magnetic field is a phenomenon where the magnetic moments within a ferromagnetic material arrange themselves in a configuration that minimizes the magnetic energy of the system, particularly the magnetic stray-field energy, without the influence of an external magnetic field. This arrangement leads to a state where the internal magnetic flux is contained within the material, effectively reducing the magnetic field to almost zero outside the material. This configuration is also known as a “closed flux” or “magnetic vortex” state. In other implementations the ferromagnetic layer (e.g., free layer) may be formed of two ferromagnetic layers, forming a SAF.

In some implementations, the MR device is used to detect or sense an external magnetic field as a response to a measured resistance. In this case, the ferromagnetic layer whose magnetic orientation is to be switched may be a magnetic reference layer and another ferromagnetic layer of the layer stack and non-adjacent to the first/second conductor may be a magnetic free layer.

In some implementations, the MR device is used as an MRAM (Magnetoresistive Random Access Memory) memory cell. In this case, the ferromagnetic layer whose magnetic orientation is to be switched may be a magnetic free layer and another ferromagnetic layer of the layer stack and non-adjacent to the first/second conductor may be a magnetic reference layer. An MRAM memory cell is a type of non-volatile memory that utilizes the magnetoresistive effect to store data. The basic principle behind MRAM is the use of magnetic states to represent bits of information, typically ‘0’ and ‘1’, and the ability to read these states through changes in electrical resistance. An MRAM memory cell typically consists of a magnetic tunnel junction (MTJ), which is made up of two ferromagnetic layers separated by a thin insulating layer (tunnel barrier). One of the ferromagnetic layers is the reference layer, whose magnetic orientation is fixed, while the other layer is the free layer, whose magnetic orientation can be switched between parallel and antiparallel alignments relative to the reference layer. The parallel alignment represents one binary state (‘1’ or ‘0’), and the antiparallel alignment represents the other (‘0’ or ‘1’).

In some implementations, the control circuit is configured to apply the second current pulse to the second conductor with a magnitude equal to or higher/smaller than the first current pulse. In this way, the magnetization of the adjacent ferromagnetic layer may be switched without a magnetic bias field. In some implementations, the magnitude (strength) of the second current pulse relative to the first current pulse may be varied.

In some implementations, a start time of the first current pulse equals a start time of the second current pulse and a duration of the first current pulse is longer than a duration of the second current pulse. In this way, the magnetization of the adjacent ferromagnetic layer may be switched without a magnetic bias field.

In some implementations, the first current pulse strength has a first functional form as function of time and the second current pulse has a different second functional form as function of time.

In some implementations, the control circuit is configured to, in a first state, apply the second current pulse with a positive polarity in addition to the first current pulse to switch magnetic orientation of the ferromagnetic layer from a first orientation (e.g., downward) to a second orientation (e.g., upward), and, in a second state, apply the second current pulse with a negative polarity to switch the magnetic orientation of the ferromagnetic layer from the second orientation (e.g., upward) to the first orientation (e.g., downward). In this way, the magnetization of the adjacent ferromagnetic layer may be switched between two states without a magnetic bias field.

In some implementations, the control circuit is further configured to provide a difference between a first sensor signal in the first state and a second sensor signal in the second state as an output sensor signal. In this way, an offset error of the MR device may be reduced.

In some implementations, the first and second conductors are arranged directly adjacent to the layer stack of the MR element (e.g., MTJ). In particular, the first and second conductors are arranged directly adjacent to the ferromagnetic layer whose magnetic orientation is to be switched. The first and second conductors may be arranged directly below or directly above the ferromagnetic layer whose magnetic orientation is to be switched. In some implementations, the first and second conductors are arranged directly adjacent to the magnetic free layer or directly adjacent to the magnetic reference layer.

In some implementations, the first and second conductors are arranged in a crossbar structure.

In some implementations, the first and second conductors include (consist of) nonmagnetic heavy metal. The heavy metal may include Pt, Ta, or W. In the context of SOT, a nonmagnetic heavy metal plays a role in generating efficient spin currents due to its strong spin-orbit coupling. Spin-orbit coupling is a relativistic effect arising from the interaction between an electron's spin and its orbital motion around the nucleus, particularly pronounced in heavy metals due to their large atomic numbers. This interaction can be harnessed to manipulate the magnetization of adjacent ferromagnetic materials without applying an external magnetic field, relying instead on electric currents through the heavy metal.

In some implementations, the MR device further includes electrodes on both ends of the layer stack for applying a current perpendicular to plane (CPP) through the layer stack.

According to a second aspect, the present disclosure provides a magnetoresistive random access memory (MRAM) cell including the MR device of any one of the previous examples.

According to a further aspect, the present disclosure provides a method for switching a magnetic orientation of a ferromagnetic layer. The method includes providing at least one MR element including a layer stack with ferromagnetic and non-magnetic layers stacked in a first direction. The layer stack of the MR element includes the ferromagnetic layer whose magnetic orientation is to be switched. The ferromagnetic layer may be a reference layer/system or a magnetic free layer of the MR element. The ferromagnetic layer may have an out-of-plane magnetization in the first direction. The method further includes providing, adjacent to the ferromagnetic layer, a first conductor extending in a second direction (e.g., x-direction) and a second conductor extending in a third direction (e.g., y-direction). The second and third directions may span a plane to which the first direction is perpendicular. For example, the second direction (e.g., x-direction) may be perpendicular to the first direction. The third direction (e.g., y-direction) may be perpendicular to the first and/or second direction. The first and second conductors are configured to induce SOT in the magnetic reference layer. The method further includes applying a first current to the first conductor and a second current to the second conductor in a temporally overlapping manner and with different time characteristics.

In some implementations, the second current is turned off before turning off the first current to switch the magnetic orientation of the ferromagnetic layer.

In some implementations, the second current is applied to the second conductor with a magnitude equal to or higher than the first current.

In some implementations, a start time of the first current equals a start time of the second current and wherein a duration of the first current is longer than a duration of the second current.

In some implementations, the method includes, in a first state, applying the second current with a positive polarity in addition to the first current to switch the magnetic orientation of the ferromagnetic layer from a first orientation to a second orientation, and, in a second state, applying the second current with a negative polarity to switch the magnetic orientation of the ferromagnetic layer from the second orientation to the first orientation.

In some implementations, the method includes providing an output sensor signal corresponding to a difference between a first sensor signal in the first state and a second sensor signal in the second state.

### BRIEF DESCRIPTION OF THE DRAWINGS

Some examples of apparatuses and/or methods will be described in the following by way of example only, and with reference to the accompanying figures, in which

FIG. 1 shows a basic structure of a MR sensing device according to an implementation;

FIG. 2 shows a transfer curve of xMR layer stack, in the case the reference layer is switched between up and down state;

FIG. 3 shows a basic structure of an MRAM cell according to an implementation;

FIG. 4 shows an implementation where multiple MR elements can be positioned on a jₓ current line, the element that should be switched can be selected by the j_{y} current;

FIG. 5 shows the principle of switching, where a combination of x and y SOT currents is applied;

FIG. 6 shows example current sequences to switching the ferromagnetic layer with SOT currents; and

FIG. 7 shows an example configuration of reference layers if the MR device is operated in a Wheatstone bridge configuration.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

MRAM has emerged as a promising candidate for a non-volatile memory cell due to its unique combination of speed and endurance. To enhance the durability of MRAM elements by separating the read-back current from the write current, SOT switching may be employed. However, SOT switching schemes require the breaking of symmetry to achieve reliable and deterministic switching, which was originally realized by applying an external field parallel to the SOT current direction. Since then, various methods to circumvent the need for an additional bias field have been proposed, as reviewed by Krizakova et al. It includes using lateral geometry asymmetries, thickness asymmetries, tilted anisotropy axis, in-plane magnets, exchange bias, combined SOT and STT, crystal symmetries. Sverdlov et al. used two SOT pulses for switching. However, magnetic field-free switching could only be achieved if a geometric overlap of about 30% of the second pulse wire with the free layer is achieved, which is technologically very difficult to produce. In addition, the “write pulse 1” is applied before the second consecutive current, which requires a very precise timing of the pulses.

The present disclosure proposes a switching scheme that (i) does not require geometrical overlap of two wires, and (ii) it does not require accurate timing of the two pulses. To demonstrate the concept, micromagnetic simulations including SOT may be performed through a damping (H_{dl}) and field-like (H_{fl}) torque term augmented to the Gilbert equation,

$${\partial }_{t} m = - γ m \times ( {H}^{eff} - {H}_{dl} m \times p - {H}_{fl} p ) + α m \times {\partial }_{t} m .$$

The damping and field like fields are defined as:

$${H}_{dl} = \frac{{j}_{e} ℏ}{2 e {μ}_{0} {tM}_{s}} \cdot {η}_{dl}$$

$${H}_{fl} = \frac{{j}_{e} ℏ}{2 e {μ}_{0} {tM}_{s}} \cdot {η}_{fl}$$

where jₑ is the applied current density, e the electron charge, t the thickness of the ferromagnetic layer where the SOT acts on, Mₛ the saturation magnetization of the ferromagnetic layer. n_{dl} and n_{fl} are the damping and field efficiencies, respectively. The normalized magnetization is denoted by m and the spin polarization direction that is produced by the SOT current is denoted by p. If a current is applied in x-direction the spin polarization of a spin current directed in z-direction may point in the y-direction.

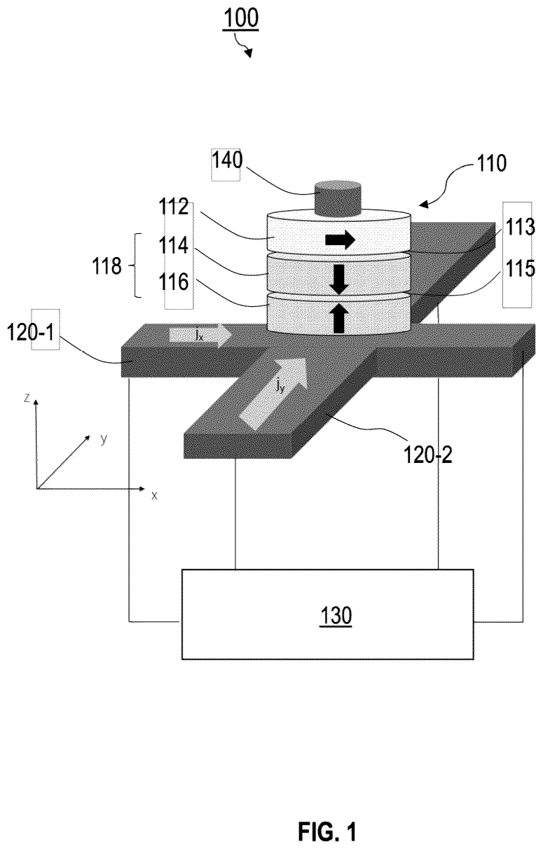

The concept presented in this disclosure is shown in FIG. 1, schematically illustrating a MR device 100 according to an implementation.

MR device 100 shown in FIG. 1 comprises an MR sensing element 110. The skilled person having benefit from the present disclosure will appreciate that MR device 100 could also comprise more than one MR sensing element 110, for example, when used in half-bridge (two MR sensing elements) or full-bridge configurations (four MR sensing elements).

MR sensing element 110 comprises a layer stack of ferromagnetic and non-magnetic layers. In the illustrated example, the ferromagnetic and non-magnetic layers of MR sensing element 110 are stacked in vertical direction (z-direction). The example layer stack of FIG. 1 comprises a first ferromagnetic layer 112 which may be configured with low coercivity (easily magnetized and demagnetized). First ferromagnetic layer 112 may act as magnetic free layer of a sensor device. Example materials for magnetic free layer 112 are NiFe (Nickel-Iron, also known as Permalloy), CoFe (Cobalt-Iron), and CoFeB (Cobalt-Iron-Boron). The magnetic free layer 112 may be a ferromagnet forming an in-plane flux closure (vortex) state at zero external magnetic field. In other implementations layer 112 can be in quasi homogenous in-plane magnetization state at zero field. Yet, in other implementations ferromagnetic layer 112 can form a SAF.

Alternatively, magnetic free layer 112 may be a ferromagnet with perpendicular crystalline anisotropy. A ferromagnet with perpendicular crystalline anisotropy refers to a type of ferromagnetic material in which the crystalline structure inherently favors magnetic moments aligning perpendicular to the plane of the material.

The layer stack of MR sensing element 110 comprises one or more second ferromagnetic layers 118 below magnetic free layer 112, which may be configured with high coercivity (maintains its magnetic orientation under external magnetic fields). Layer(s) 118 may act as magnetic reference layer/system against which the orientation of the magnetic free layer 112 is compared. The example illustrated in FIG. 1 involves using a synthetic antiferromagnet (SAF) structure for the magnetic reference layer 118. SAFs comprise two (or more) ferromagnetic layers 114, 116 separated by a nonmagnetic coupling layer (often ruthenium, Ru. Also other 3d, 4d and 5d transition metals can be used such as V, Nb, Mo, Ta, W, Re, and Ir) 115. The coupling layer 115 induces antiferromagnetic coupling between the ferromagnetic layers 114, 116. This arrangement can enhance the stability of the reference layer's 118 magnetic orientation.

In implementations related to TMR sensing elements, a non-magnetic layer 113 between magnetic free layer 112 and magnetic reference layer/system 118 may be configured as a tunnel barrier. The tunnel barrier 113 may be made from materials such as aluminum oxide (Al₂O₃) or magnesium oxide (MgO), which are insulators that can be made into very thin layers while maintaining their insulating properties.

In implementations related to GMR sensing elements, the non-magnetic layer 113 between magnetic free layer 112 and magnetic reference layer/system 118 may be configured as a conducting spacer layer. Example materials for the spacer layer 113 include copper (Cu), silver (Ag), or gold (Au).

While magnetic free layer 112 has an in-plane (in x-y-plane) magnetization in the example illustrated in FIG. 1, the magnetic reference layer/SAF 118 has an out-of-plane reference magnetization in vertical direction (z-direction). For example, ferromagnetic layer 116 may be a ferromagnet with perpendicular magnetic anisotropy (PMA). The coupling layer 115 of SAF 118 facilitates antiferromagnetic coupling between the adjacent ferromagnetic layers 114, 116. This antiferromagnetic coupling ensures that the magnetic moments of the ferromagnetic layers 114, 116 are oriented in opposite directions (antiparallel alignment).

Below the layer stack of MR sensing element 110 (below ferromagnetic layer 116), MR device 100 further comprises a first electric conductor 120-1 extending in x-direction and a second conductor 120-2 extending in y-direction. Thus, in the illustrated example, the first and second conductors 120-1, 120-2 are arranged in a crossbar structure, wherein the layer stack of MR sensing element 110 is placed at the intersection point of the first and second conductors 120-1, 120-2. The skilled person having benefit from the present disclosure will appreciate that the first and second conductors 120-1, 120-2 do not necessarily have to be arranged perpendicular to each other.

MR sensing element 110 is configured to induce SOT in the magnetic reference layer/SAF 118 by using the first and second conductors 120-1, 120-2. A plane or layer spanned by the first and second conductors 120-1, 120-2 may also be referred to as SOT layer. The first and second conductors 120-1, 120-2 may comprise (consist of) nonmagnetic heavy metal, such as Pt, Ta, or W. In the context of SOT, a nonmagnetic heavy metal plays a role in generating efficient spin currents due to its strong spin-orbit coupling. When a current-carrying nonmagnetic heavy metal is coupled to a ferromagnetic layer, a phenomenon known as the spin Hall effect (SHE) can occur, leading to the generation of a spin current perpendicular to the charge current. This interaction may have implications for spintronic devices and may be leveraged to create ways of manipulating magnetic moments in ferromagnetic materials without applying an external magnetic field. The spin Hall effect (SHE) in nonmagnetic heavy metals arises due to the strong spin-orbit coupling in these materials. When an electric current flows through such a metal, it causes electrons with opposite spins to deflect in opposite directions, creating a transverse spin current. This effect generates a spin accumulation on the opposite sides of the material, with a spin polarization perpendicular to the direction of the charge current. When the spin current generated by the SHE in the heavy metal layer 120-1, 120-2 enters the (directly) adjacent ferromagnetic layer 116, it can exert a torque on the magnetization of the ferromagnet. This torque can be used to manipulate the magnetic state of the ferromagnetic layer 116, including switching its magnetization direction. This process is known as spin-transfer torque (STT) when it involves direct transfer of spin angular momentum from conduction electrons to the magnetization, and spin-orbit torque (SOT) when it specifically involves torques generated by spin-orbit effects, such as those from the SHE. The torque can reorient the magnetization direction, allowing for the magnetic state of the ferromagnetic layer 116 to be switched between different stable configurations (e.g., from parallel to antiparallel relative to a reference orientation). This capability may also be useful for memory devices like MRAM, where it enables writing of information without the need for magnetic fields.

MR device 100 further comprises a control circuit 130 which is configured to apply a first current pulse to the first conductor 120-1 and to apply a second current pulse to the second conductor 120-2 in a temporally overlapping manner. That is, the first and second current pulse overlap in time. The first and the second current pulse have different time characteristics.

For example, the control circuit 130 may be configured to lower the strength of or turn off the second current pulse before lowering the strength of or turning off the first current pulse. A current pulse refers to a transient flow of electric current that may change abruptly in amplitude and may last for a limited duration of time before returning to its initial value or zero. Current pulses may be characterized by their shape (such as square, triangular, or sinusoidal), amplitude (the maximum current level), duration (the length of time the pulse lasts), and repetition rate (how frequently pulses occur over time).

Further, control circuit 130 may be configured to apply the second current pulse to the second conductor 120-2 with a magnitude equal to or higher/smaller than the first current pulse. In this way, the reference magnetization of adjacent layer 116 may be switched without a magnetic bias field. In some implementations, a start time of the first current pulse may equal a start time of the second current pulse, and a duration of the first current pulse may be longer than a duration of the second current pulse.

The electrical currents in the SOT layer are applied via at least two current lines (such as jₓ and j_{y}) or conductors 120-1, 120-2 spanning the SOT layer. This may facilitate the reversal of the adjacent magnetic reference layer 116 and 114 (or 118) with perpendicular magnetization (in z-direction). Unlike conventional switching schemes, the proposed method does not require additional external fields like a Bₓ field. The magnetic reference layer 118 to be switched can form a SAF (comprising two antiparallel coupled layers 114 and 116). In other implementations, the magnetic reference layer 118 may consist solely of one layer 116. If the magnetization of ferromagnetic layer 116 reverses due to the strong coupling via SOT layer spanned by conductors 120-1, 120-2, ferromagnetic layer 114 will also reverse. The coupling layer 115 in between layers 114, 116 could be any layer that promotes strong coupling, such as strong antiferromagnetic coupling via materials like Ru or Gd. Furthermore, it might be beneficial to utilize coupling layers that also encourage strong perpendicular anisotropy.

The proposed switching scheme can be utilized for various applications, including advanced MR sensors.

FIG. 1 illustrates schematics of the proposed MR device 100, which includes a free layer 112 which may possess zero magnetization in the perpendicular direction (z-direction) when no external magnetic field is applied. This can be achieved by utilizing a layer that exhibits in-plane magnetization. Alternatively, a layer with perpendicular anisotropy that fragments into multidomain areas with both upward and downward magnetization can be used. In other implementations, the free layer 112 may manifest a flux closure state. Yet in other implementations the free layer is formed as a SAF. Examples of flux closure states include a vortex configuration or an antiparallel coupled layer structure for the free layer 112. For sensor applications, the magnetization might exist in the plane of the free layer 112.

When an external magnetic field is applied in the perpendicular direction (z-direction), the magnetization component in the free layer 112 amplifies with increasing field strength. A sensor response can be measured due to the TMR or GMR effects when a current (CPP) is channeled through connections/electrodes 140 and 120 on the upper and lower end of the layer stack. The sensor response depends on the magnetic states in layers 118 and 112. Layer 113 might serve as a tunnel barrier (TMR) or a conducting material (GMR).

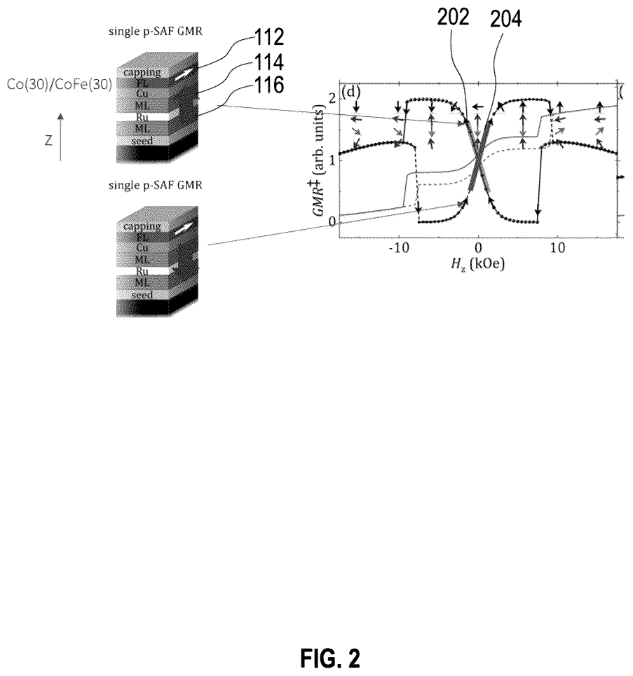

Depending on the state of the reference layer(s) 118, the sensor's transfer curve with regard to perpendicular fields might invert, as depicted in FIG. 2. Here, the transfer curve 202 represents a scenario where the magnetization of the reference layer 116 is oriented upward (first state), and a positive applied external field indicates a magnetic field also pointing upward. The transfer curve reverses when the reference layer 116 alternates to a second state where the magnetization of the reference layer 116 is oriented downward. This behavior may be used and the control circuit 130 may be configured to, in the first state, apply the second current pulse with a negative polarity in addition to the first current pulse to switch the reference magnetization of the magnetic reference 116 layer from a first orientation (e.g., upward) to a second orientation (e.g., downward), and, in the second state, apply the second current pulse with a positive polarity to switch the reference magnetization of the magnetic reference layer 116 from the second orientation (e.g., downward) to the first orientation (e.g., upward). The ultimate sensor signal may then be the difference between these two responses. Thus, control circuit 130 may be configured to provide a difference between a first sensor signal in the first state and a second sensor signal in the second state as an output sensor signal. In the example provided in FIG. 2, the reference layer 118 is a magnetic multilayer, and the free layer 112 comprises a Co(3 nm)/CoFe(3 nm) structure. Another version of the reference layer 118 is CoFeB(0.9)/Ru/CoFeB(0.9)/MgO, where the CoFeB/MgO interface encourages perpendicular anisotropy. The free layer 112 might be a slightly thicker CoFeB layer, such as CoFeB(1.1), promoting in-plane magnetization.

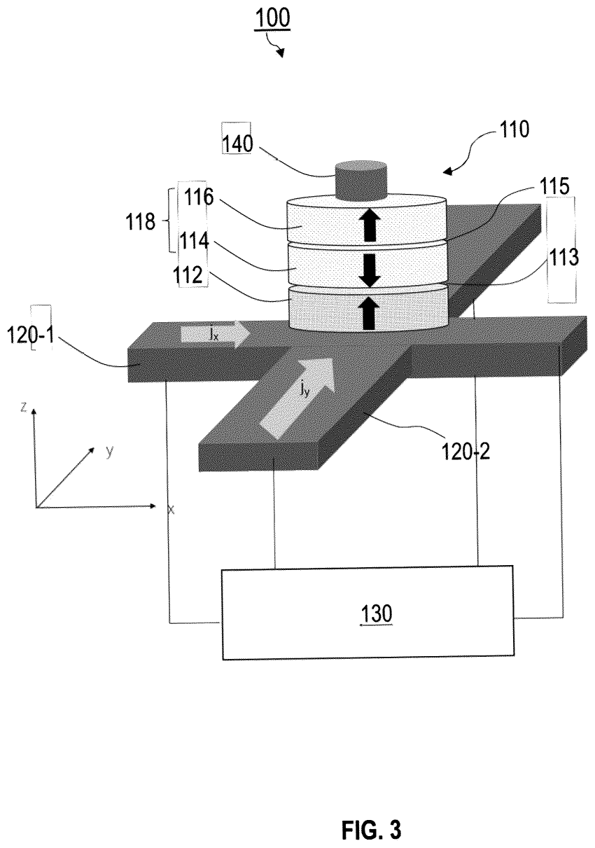

Another example implementation of MR device 100 is shown in FIG. 3, where the order of the ferromagnetic and non-magnetic layers is reversed compared to the example of FIG. 1.

MR device 100 shown in FIG. 3 may be used for MRAM-like structures. The layer stack of MR sensing element 110 comprises magnetic free layer 112 (representing a stored bit) adjacent to and directly on top of the first and second conductors 120-1, 120-2 of SOT layer. Non-magnetic layer 113 is arranged on top of magnetic free layer 112 and separates magnetic free layer 112 from reference layer/SAF 118. Upper electrode 140 is arranged on top of ferromagnetic layer 116. In the example of FIG. 3, free layer 112 adjacent to first and second conductors 120-1, 120-2 is a ferromagnet with perpendicular crystalline anisotropy in which the crystalline structure inherently favors magnetic moments aligning perpendicular to the plane of the material. This property is known as perpendicular magnetic anisotropy (PMA) at the crystalline level.

Here, control circuit 130 may be used to switch between two different states of free layer 112, representing different stored bits. Control circuit 130 may be configured to, in a first state (e.g., bit “1”), apply the second current pulse with a first polarity in addition to the first current pulse to switch the reference magnetization of the magnetic reference 116 layer from a first orientation (e.g., upward) to a second orientation (e.g., downward). The second orientation corresponds to a second state (e.g., bit “0”). Control circuit 130 may be also configured to, in the second state (e.g., bit “0”), apply the second current pulse with a second (opposite) polarity to switch the reference magnetization of the magnetic free layer 112 from the second orientation (e.g., downward) to the first orientation (e.g., upward). The first orientation corresponds to the first state (e.g., bit “1”).

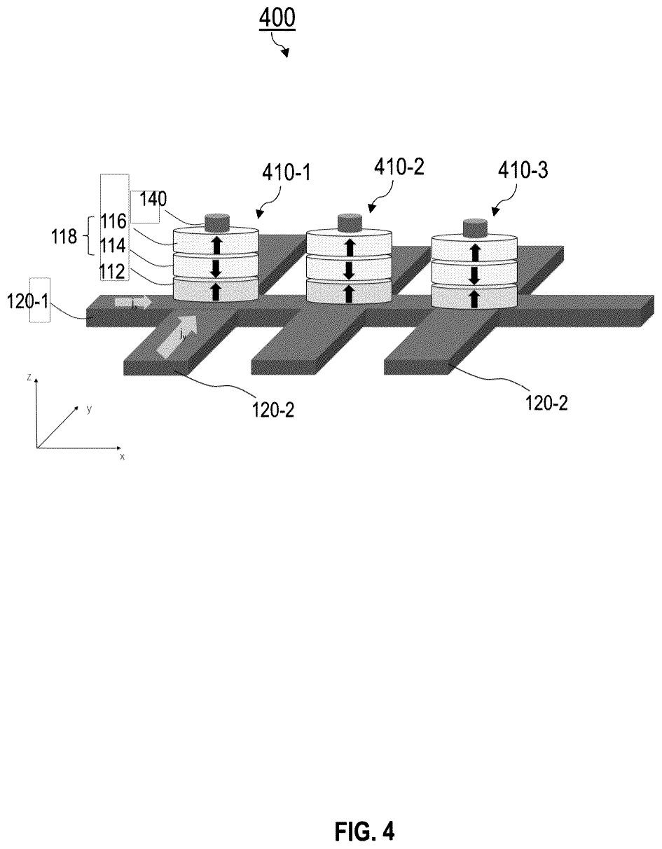

FIG. 4 illustrates a realization of an MRAM structure 400, where multiple storage MRAM cells 410-1, 410-2, 410-3 are deposited onto a single SOT heavy metal layer with respective first and second conductors 120-1, 120-2 associated to each MRAM cell 410-1, 410-2, 410-3. The MRAM cells 410-1, 410-2, 410-3 are all commonly associated with first conductor 120-1 extending in x-direction. MRAM cell 410-1 is associated with a first second conductor 120-2 extending in y-direction. MRAM cell 410-2 is associated with a second second conductor 120-2 extending in y-direction. MRAM cell 410-3 is associated with a third second conductor 120-2 extending in y-direction. The respective MRAM cell 410 to be switched may be selected by applying a respective j_{y} current through the respective second conductor 120-2 in addition to the jₓ current through the first conductor 120-1.

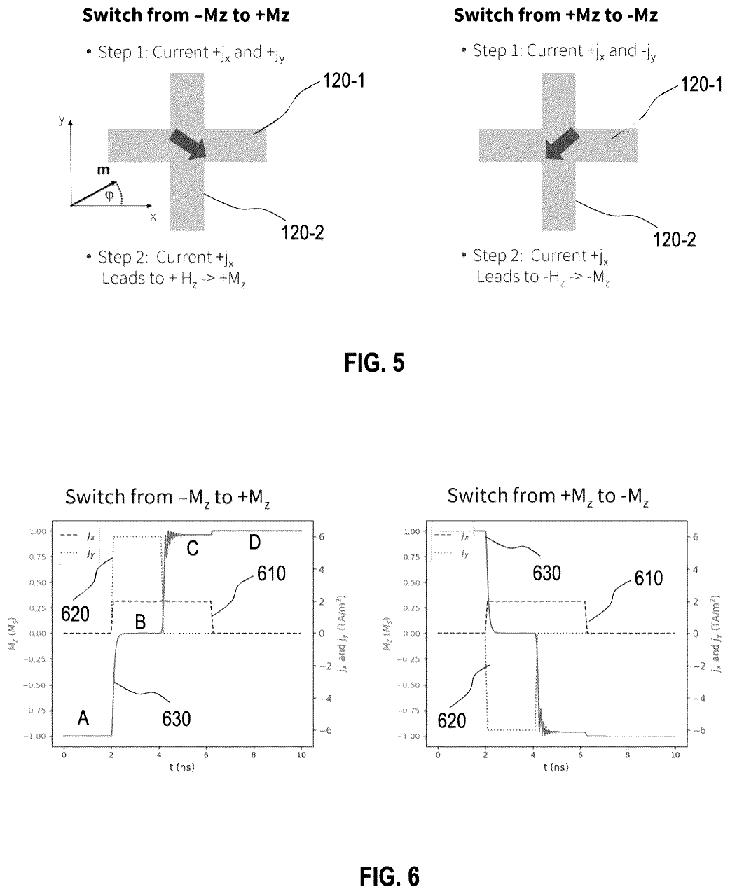

In the following, the fundamental concept of the SOT switching process is detailed and summarized in FIG. 5.

Initially, control circuit 130 applies two currents in the jₓ and j_{y} directions, respectively, via the first and second conductors 120-1, 120-2 resembling a Hall cross. In this context, the total current density at the intersection point of the first and second conductors 120-1, 120-2 is sufficiently large to overcome the perpendicular anisotropy of layer 116 (FIG. 1) or layer 112 (FIG. 3). Owing to the damping effect and the field-like torque term, the magnetization rotates within the plane. The j_{y} current is employed to facilitate an Mₓ component of the magnetization. Depending on whether a positive or negative j_{y} current is applied, one achieves a positive or negative Mₓ component, which subsequently determines the final +M_{z} or −M_{z} state, respectively.

After the j_{y} current through second conductor 120-2 is discontinued, only the jₓ current through first conductor 120-1 persists, with a magnitude that is sufficiently small to prevent the establishment of an out-of-plane component of the magnetization. After the jₓ current is discontinued, depending on whether the initial state possessed a positive or negative Mₓ component, the final magnetic state of layer 116 (FIG. 1) or layer 112 (FIG. 3) will be either +M_{z} or −M_{z}.
(i) In the first step, currents are applied along the first and second conductors 120-1, 120-2. Consequently, in the region beneath layer 116 (FIG. 1) or layer 112 (FIG. 3), the total current is the vectorial sum of these two individual currents. These currents are selected to be sufficiently strong, ensuring that they exceed the critical current required to switch the magnetization to an in-plane orientation. When the currents surpass this critical threshold, the equilibrium magnetization aligns in-plane and orthogonally to the total current direction. The in-plane orientation is thus determined by the relative strengths of the jₓ and j_{y} currents. For instance, if j_{y} is significantly larger than jₓ, the magnetization will predominantly orient in a direction close to the x-axis. If j_{y}˜jₓ the magnetization will point at an angle of −45° with respect to the x-axis.
(ii) In the second step, the j_{y} current is turned off. If the remaining jₓ current is less than the critical current needed for in-plane switching, the magnetization will rotate out-of-the plane towards the z-direction. This rotation is facilitated by the initial Mₓ component of the magnetization, acting similarly to the application of an Hₓ field, which is usually required for deterministic Spin-Orbit Torque (SOT) switching.

FIG. 6 presents a detailed depiction of the magnetization dynamics influenced by applied jₓ and j_{y} currents over a specific time.

In the left graph of FIG. 6, the applied jₓ and j_{y} currents are shown by lines 610, 620, whereas the M_{z} component of the magnetization of layer 116 (FIG. 1) or layer 112 (FIG. 3) is illustrated by reference numeral 630. Before time 2 ns, neither the first nor the second current pulse is applied and the system finds itself in state A, e.g., the magnetization of the layer 116 (FIG. 1) or layer 112 (FIG. 3) is in a first orientation (e.g., −M_{z}). In this state A, the control circuit 130 may be configured (at time 2 ns) to apply the second current pulse (j_{y}) with a positive polarity in addition to the first current pulse (jₓ) to switch the magnetization of the layer 116 (FIG. 1) or layer 112 (FIG. 3) from the first orientation (e.g., −M_{z}) to a second orientation (e.g., +M_{z}). During the duration of the second current pulse (j_{y}) (e.g., the time interval of 2 to 4 ns), the system finds itself in state B. At this juncture, the collective strength of jₓ and j_{y} currents sums up to 8 TA/m². This amount of current is sufficiently strong to rotate the magnetization in plane. As we progress into the time window between 4 and 6 ns, in which the second current pulse (j_{y}) has been turned off and the first current pulse (jₓ) is still active, only the jₓ current remains active, exerting a reduced current strength of 2 TA/m².

Thus, the control circuit 130 may be configured to, in a first state (state A), apply the second current pulse with a positive polarity in addition to the first current pulse to switch the magnetization of the layer 116 (FIG. 1) or layer 112 (FIG. 3) from a first orientation (e.g., −M_{z}) to a second orientation (e.g., +M_{z}). In a second state (shown in the right graph), the control circuit 130 may be configured to apply the second current pulse with a negative polarity to switch the magnetization of the layer 116 (FIG. 1) or layer 112 (FIG. 3) from the second orientation (e.g., +M_{z}) to the first orientation (e.g., −M_{z}). In the illustrated example, the start time of the first current pulse substantially equals the start time of the second current pulse and a duration of the first current pulse is longer than a duration of the second current pulse. In other implementations, the start time may not be equal. In the illustrated example, the control circuit 130 is configured to apply the second current pulse (j_{y}) to the second conductor 120-2 with a magnitude equal to or higher than the first current pulse (jₓ). In other implementations, it might be beneficial if the pulses are not completely switched off but the strength can take a functional form as function of time.

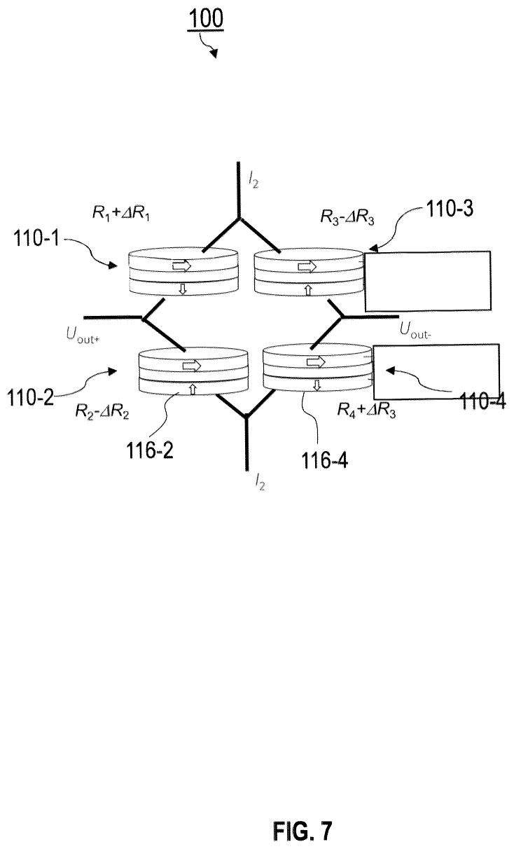

The output of the MR device 100 can be also realized by using a Wheatstone bridge illustrated in FIG. 7.

The MR device 100 of FIG. 7 comprises four MR sensing elements 110-1, . . . , 110-4 in Wheatstone bridge configuration. The output voltage of the Wheatstone bridge configuration depends on,

$${U}_{out} = {U}_{0} \frac{{R}_{1} {R}_{4} - {R}_{3} {R}_{2}}{( {R}_{1} + {R}_{2} ) ( {R}_{3} + {R}_{4} )}$$

$$where {U}_{0} = {R}_{t o t} {I}_{2} .$$

If the current polarity is changed from an original polarity (e.g., +I₂) to a reversed polarity (e.g., −I₂) and the orientation of all reference layers 116 remains the same as shown in FIG. 7 (this state may be denoted as ref1), the output of the Wheatstone bridge reverses sign. If, in addition to the reversed current polarity, also the magnetization state of each reference layers 116 is reversed due to SOT (this state may be denoted as ref2) the output of the Wheatstone bridge remains the same again. Hence, the total output voltage may be the sum of the Wheatstone bridge output for these two reversed states, where the I2 current is used to reverse the reference layer magnetization.

$${U}_{signal} = {U}_{out , I 2 + , ref 1} + {U}_{out , I 2 + , ref 2}$$

In some implementations the sensor might be operated by reversing the orientation of the reference layers by SOT currents and reversing the sign of the bridge input current, and averaging the output of the bridge over these two periods of time. Thus, the control circuit 130 (not shown) may be configured to provide a combination of the first output of the Wheatstone bridge in the first state (ref1) and the second output of the Wheatstone bridge in the second state (ref2) as an output sensor signal.

In other implementations. the current jₓ and j_{y} are applied to set the reference layers (ref1) as shown in FIG. 7. A constant current I₂ is applied to measure the output U_{out, ref1} of the Wheatstone bridge. Then jₓ and j_{y} are applied to reverse the magnetization state of the reference layers (ref1). With the constant current I₂ the output U_{out, ref2} is measured. The signal that is proportional to the applied field in z-direction is given by

$${U}_{signal} = {U}_{out , I 2 + , ref 1} + {U}_{out , I 2 + , ref 2}$$

Some implementations of the present disclosure propose a magnetic sensor device comprising a GMR or TMR sensor element where the transfer function of the sensor device can be reversed by changing the orientation of the magnetic reference system. The reference system can be switched by using a SOT current. An advantage is that offsets of the sensor can be reduced and switching can be realized without bias fields.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### Aspects

The following provides an overview of some Aspects of the present disclosure:

Aspect 1: A magnetoresistive device, comprising: a magnetoresistive element comprising a layer stack of ferromagnetic layers and non-magnetic layers stacked in a first direction, the layer stack comprising a ferromagnetic layer having a magnetic orientation to be switched; adjacent to the ferromagnetic layer, a first conductor extending in a second direction and a second conductor extending in a third direction, wherein the first conductor and the second conductor are configured to induce spin-orbit torque (SOT) in the ferromagnetic layer; and a control circuit configured to apply a first current pulse to the first conductor and a second current pulse to the second conductor in a temporally overlapping manner and with different time characteristics.

Aspect 2: The magnetoresistive device of Aspect 1, wherein the control circuit is configured to turn off the second current pulse before turning off the first current pulse to switch the magnetic orientation of the ferromagnetic layer.

Aspect 3: The magnetoresistive device of any of Aspects 1-2, wherein the ferromagnetic layer having the magnetic orientation to be switched is a ferromagnet with perpendicular anisotropy.

Aspect 4: The magnetoresistive device of any of Aspects 1-3, wherein the layer stack comprises a magnetic free layer and a magnetic reference layer, wherein the ferromagnetic layer having the magnetic orientation to be switched is the magnetic reference layer.

Aspect 5: The magnetoresistive device of Aspect 4, wherein the magnetic reference layer is configured as a synthetic antiferromagnet (SAF).

Aspect 6: The magnetoresistive device of Aspect 4, wherein the magnetic free layer comprises an in-plane magnetization in absence of an external magnetic field.

Aspect 7: The magnetoresistive device of Aspect 4, wherein the magnetic free layer is a ferromagnet with perpendicular crystalline anisotropy.

Aspect 8: The magnetoresistive device of any of Aspects 1-7, wherein the layer stack comprises a magnetic free layer and a magnetic reference layer, wherein the ferromagnetic layer having the magnetic orientation to be switched is the magnetic free layer.

Aspect 9: The magnetoresistive device of Aspect 4, wherein the magnetic free layer and the magnetic reference layer are separated by a non-magnetic tunnel barrier.

Aspect 10: The magnetoresistive device of Aspect 4, wherein the magnetic free layer and the magnetic reference layer are separated by a non-magnetic conducting spacer layer.

Aspect 11: The magnetoresistive device of any of Aspects 1-10, wherein the control circuit is configured to apply the second current pulse to the second conductor with a magnitude equal to or higher than the first current pulse.

Aspect 12: The magnetoresistive device of any of Aspects 1-11, wherein a start time of the first current pulse equals a start time of the second current pulse and wherein a duration of the first current pulse is longer than a duration of the second current pulse.

Aspect 13: The magnetoresistive device of any of Aspects 1-12, wherein the control circuit is configured to: in a first state, apply the second current pulse with a first polarity in addition to the first current pulse to switch the magnetic orientation of the ferromagnetic layer from a first orientation to a second orientation, and in a second state, apply the second current pulse with a second polarity, opposite to the first polarity, to switch the magnetic orientation of the ferromagnetic layer from the second orientation to the first orientation.

Aspect 14: The magnetoresistive device of Aspect 13, wherein the control circuit is further configured to provide a difference between a first sensor signal obtained in the first state and a second sensor signal obtained in the second state as an output sensor signal.

Aspect 15: The magnetoresistive device of any of Aspects 1-14, wherein the first conductor and the second conductor are arranged in a crossbar structure.

Aspect 16: The magnetoresistive device of any of Aspects 1-15, wherein the first conductor and the second conductor consist of nonmagnetic heavy metal.

Aspect 17: The magnetoresistive device of any of Aspects 1-16, wherein the layer stack forms a giant magnetoresistance (GMR) spin-valve structure or a tunnel magnetoresistance (TMR) spin-valve structure.

Aspect 18: The magnetoresistive device of any of Aspects 1-17, further comprising: electrodes on both ends of the layer stack for applying a current perpendicular to plane (CPP).

Aspect 19: A magnetoresistive random access memory cell, comprising: a magnetoresistive element comprising a layer stack of ferromagnetic layers and non-magnetic layers stacked in a first direction, the layer stack comprising a ferromagnetic layer having a magnetic orientation to be switched; adjacent to the ferromagnetic layer, a first conductor extending in a second direction and a second conductor extending in a third direction, wherein the first conductor and the second conductor are configured to induce spin-orbit torque (SOT) in the ferromagnetic layer; and a control circuit configured to apply a first current pulse to the first conductor and a second current pulse to the second conductor in a temporally overlapping manner and with different time characteristics.

Aspect 20: A method for switching a magnetic orientation, the method comprising: providing a magnetoresistive element comprising a layer stack of ferromagnetic layers and non-magnetic layers stacked in a first direction, the layer stack comprising a ferromagnetic layer having a magnetic orientation to be switched; providing, adjacent to the ferromagnetic layer, a first conductor extending in a second direction and a second conductor extending in a third direction, the first conductor and the second conductor being configured to induce spin-orbit torque in the ferromagnetic layer; applying a first current to the first conductor and applying a second current to the second conductor in a temporally overlapping manner and with different time characteristics.

Aspect 21: The method of Aspect 20, wherein the second current is turned off before turning off the first current to switch the magnetic orientation of the ferromagnetic layer.

Aspect 22: The method of any of Aspects 20-21, wherein the second current is applied to the second conductor with a magnitude equal to or higher than the first current.

Aspect 23: The method of any of Aspects 20-22, wherein a start time of the first current equals a start time of the second current, and wherein a duration of the first current is longer than a duration of the second current.

Aspect 24: The method of any of Aspects 20-23, further comprising: in a first state, applying the second current with a positive polarity, in addition to the first current, to switch the magnetic orientation of the ferromagnetic layer from a first orientation to a second orientation, and in a second state, applying the second current with a negative polarity to switch the magnetic orientation of the ferromagnetic layer from the second orientation to the first orientation.

Aspect 25: The method of Aspect 24, further comprising: providing an output sensor signal corresponding to a difference between a first sensor signal obtained in the first state and a second sensor signal obtained in the second state.

Aspect 26: A system configured to perform one or more operations recited in one or more of Aspects 1-25.

Aspect 27: An apparatus comprising means for performing one or more operations recited in one or more of Aspects 1-25.

1. A magnetoresistive device, comprising:
a magnetoresistive element comprising a layer stack of ferromagnetic layers and non-magnetic layers stacked in a first direction, the layer stack comprising a ferromagnetic layer having a magnetic orientation to be switched;
adjacent to the ferromagnetic layer, a first conductor extending in a second direction and a second conductor extending in a third direction, wherein the first conductor and the second conductor are configured to induce spin-orbit torque (SOT) in the ferromagnetic layer; and
a control circuit configured to apply a first current pulse to the first conductor and a second current pulse to the second conductor in a temporally overlapping manner and with different time characteristics.

2. The magnetoresistive device of claim 1, wherein the control circuit is configured to turn off the second current pulse before turning off the first current pulse to switch the magnetic orientation of the ferromagnetic layer.

3. The magnetoresistive device of claim 1, wherein the ferromagnetic layer having the magnetic orientation to be switched is a ferromagnet with perpendicular anisotropy.

4. The magnetoresistive device of claim 1, wherein the layer stack comprises a magnetic free layer and a magnetic reference layer, wherein the ferromagnetic layer having the magnetic orientation to be switched is the magnetic reference layer.

5. The magnetoresistive device of claim 4, wherein the magnetic reference layer is configured as a synthetic antiferromagnet (SAF).

6. The magnetoresistive device of claim 4, wherein the magnetic free layer comprises an in-plane magnetization in absence of an external magnetic field.

7. The magnetoresistive device of claim 4, wherein the magnetic free layer is a ferromagnet with perpendicular crystalline anisotropy.

8. The magnetoresistive device of claim 1, wherein the layer stack comprises a magnetic free layer and a magnetic reference layer, wherein the ferromagnetic layer having the magnetic orientation to be switched is the magnetic free layer.

9. The magnetoresistive device of claim 4, wherein the magnetic free layer and the magnetic reference layer are separated by a non-magnetic tunnel barrier.

10. The magnetoresistive device of claim 4, wherein the magnetic free layer and the magnetic reference layer are separated by a non-magnetic conducting spacer layer.

11. The magnetoresistive device of claim 1, wherein the control circuit is configured to apply the second current pulse to the second conductor with a magnitude equal to or higher than the first current pulse.

12. The magnetoresistive device of claim 1, wherein a start time of the first current pulse equals a start time of the second current pulse and wherein a duration of the first current pulse is longer than a duration of the second current pulse.

13. The magnetoresistive device of claim 1, wherein the control circuit is configured to:
in a first state, apply the second current pulse with a first polarity in addition to the first current pulse to switch the magnetic orientation of the ferromagnetic layer from a first orientation to a second orientation, and
in a second state, apply the second current pulse with a second polarity, opposite to the first polarity, to switch the magnetic orientation of the ferromagnetic layer from the second orientation to the first orientation.

14. The magnetoresistive device of claim 13, wherein the control circuit is further configured to provide a difference between a first sensor signal obtained in the first state and a second sensor signal obtained in the second state as an output sensor signal.

15. The magnetoresistive device of claim 1, wherein the first conductor and the second conductor are arranged in a crossbar structure.

16. The magnetoresistive device of claim 1, wherein the first conductor and the second conductor consist of nonmagnetic heavy metal.

17. The magnetoresistive device of claim 1, wherein the layer stack forms a giant magnetoresistance (GMR) spin-valve structure or a tunnel magnetoresistance (TMR) spin-valve structure.

18. The magnetoresistive device of claim 1, further comprising:
electrodes on both ends of the layer stack for applying a current perpendicular to plane (CPP).

19. A magnetoresistive random access memory cell, comprising:
a magnetoresistive element comprising a layer stack of ferromagnetic lavers and non-magnetic lavers stacked in a first direction, the layer stack comprising a ferromagnetic layer having a magnetic orientation to be switched;
adjacent to the ferromagnetic layer, a first conductor extending in a second direction and a second conductor extending in a third direction, wherein the first conductor and the second conductor are configured to induce spin-orbit torque (SOT) in the ferromagnetic layer; and
a control circuit configured to apply a first current pulse to the first conductor and a second current pulse to the second conductor in a temporally overlapping manner and with different time characteristics.

20. A method for switching a magnetic orientation, the method comprising:
providing a magnetoresistive element comprising a layer stack of ferromagnetic layers and non-magnetic layers stacked in a first direction, the layer stack comprising a ferromagnetic layer having a magnetic orientation to be switched;
providing, adjacent to the ferromagnetic layer, a first conductor extending in a second direction and a second conductor extending in a third direction, the first conductor and the second conductor being configured to induce spin-orbit torque in the ferromagnetic layer;
applying a first current to the first conductor and applying a second current to the second conductor in a temporally overlapping manner and with different time characteristics.

21. The method of claim 20, wherein the second current is turned off before turning off the first current to switch the magnetic orientation of the ferromagnetic layer.

22. The method of claim 20, wherein the second current is applied to the second conductor with a magnitude equal to or higher than the first current.

23. The method of claim 20, wherein a start time of the first current equals a start time of the second current, and
wherein a duration of the first current is longer than a duration of the second current.

24. The method of claim 20, further comprising:
in a first state, applying the second current with a positive polarity, in addition to the first current, to switch the magnetic orientation of the ferromagnetic layer from a first orientation to a second orientation, and
in a second state, applying the second current with a negative polarity to switch the magnetic orientation of the ferromagnetic layer from the second orientation to the first orientation.

25. The method of claim 24, further comprising:
providing an output sensor signal corresponding to a difference between a first sensor signal obtained in the first state and a second sensor signal obtained in the second state.
